(19) United States
(12) Patent Application Publication
(10) Pub. No.: US 2011/0299996 A1
(43) Pub. Date: Dec. 8, 2011

(54) ANTI-EROSION COATING SYSTEM FOR GAS TURBINE COMPONENTS

(75) Inventors: Thomas Uihlein, Dachau (DE); Wolfgang Eichmann, Puchheim (DE); Falko Heutling, Muenchen (DE)

(73) Assignee: MTU Aero Engines GmbH, Munich (DE)

(21) Appl. No.: 13/202,260

(22) PCT Filed: Jan. 30, 2010
(86) PCT No.: PCT/DE10/00102

§ 371 Date: Aug. 18, 2011

(30) Foreign Application Priority Data
Feb. 21, 2009 (DE) 10-2009-010110.1

(51) Int. Cl. F01D 5/14; C23F 13/06; B05D 1/18; C23C 4/12; B05D 5/00; B05D 1/02; C23F 13/00; C23C 16/44

(52) U.S. Cl. 416/241 R; 204/196.01; 204/196.38; 427/255.7; 427/446

(57) ABSTRACT

A gas turbine component and a method for producing an anti-erosion coating system are disclosed. The gas turbine component includes a basic material, on which an anti-erosion coating system is provided that is a multilayer system including at least one ductile metal layer and at least one hard, ceramics-containing layer for forming a partial anti-erosion system. At least one anti-corrosion layer that has a lower electrochemical potential than the basic material is provided between the partial anti-erosion system and the basic material, thus providing cathodic corrosion protection.

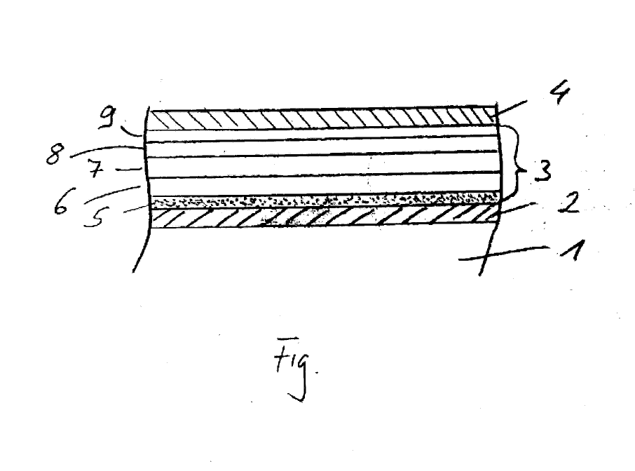

This application claims the priority of International Application No. PCT/DE2010/000102, filed Jan. 30, 2010, and German Patent Document No. 10 2009 010 110.1, filed Feb. 21, 2009, the disclosures of which are expressly incorporated by reference herein.

### BACKGROUND OF THE INVENTION

1. Field of the Invention

The invention relates to a gas turbine component made of a basic material, on which an anti-erosion coating system is provided that comprises a multilayer system including at least one ductile metal layer and at least one hard, ceramics-containing layer as well as a corresponding method for producing such a gas turbine component.

2. Prior Art

Gas turbine components, such as, for example, rotor blades, guide blades or shrouds, are subject to diverse influences, the result of which is that these types of components must have diverse properties. For example, these kinds of components must have sufficient strength to withstand corresponding stresses such as centrifugal forces and the like. In addition, because of the high flow rates with which the inducted air is moved through the turbine, signs of erosion may appear on the surfaces of the gas turbine components. Accordingly, it is known to provide anti-erosion layers for these components, which are supposed to prevent an erosive removal of the basic material forming the gas turbine components. These types of anti-erosion systems are described for example in DE 10 2007 027 335 A1, DE 10 2004 001 392 A1, EP 0 674 020 A1, EP 0 562 108 B1 or EP 0 366 289 A1. These anti-erosion layers typically have multiple sublayers made of ductile metal materials and hard, ceramics-containing layers, which are arranged in some cases multiple times on top of one another.

Due to the temperature fluctuations and differences in the composition of the atmosphere to which aircraft turbines in particular are subject, the corrosive attack of the basic material in the case of gas turbine components having these types of erosion coatings may be intensified if the anti-erosion layer has defects or damage such as, for example, cracks or pores and the like

According to EP 1 548 153 B1, an attempt is made to avoid this problem by applying a thermally sprayed metal/ceramic layer, a so-called cermet, beneath the anti-erosion layer deposited by means of vapor deposition in order to prevent the crack formation.

### DISCLOSURE OF THE INVENTION

### Object of the Invention

Therefore, the object of the invention is making available an anti-erosion coating for gas turbine components as well as corresponding gas turbine components in which the problem of an intensified corrosive attack of the basic material in the event of damage to the anti-erosion layer is prevented. At the same time, expenditures for producing the anti-erosion layer are kept low without affecting the remaining properties of the gas turbine components, particularly erosion resistance, strength and the like.

### Technical Solution

The invention proceeds from the knowledge that the corrosive attack of the basic material beneath the anti-erosion coating comes about in the prior art in that, in moist and aqueous environments like those that are in effect when using gas turbines because of the corresponding humidity, a so-called local element forms, wherein the basic material normally has a lower electrochemical potential than the anti-erosion layer, which results in an attack of the basic material. This is counteracted according to the invention in that a cathodic anti-corrosion layer is configured between the partial anti-corrosion system, which forms the actual anti-erosion coating, and the basic material. The cathodic corrosion protection is thereby based on the formation of a corresponding local element through the cathodic anti-corrosion layer and the basic material, in which the basic material has the higher electrochemical potential so that the cathodic anti-corrosion layer as the sacrificial anode with lower potential is dissolved, while the basic material is protected.

A correspondingly configured anti-erosion coating system includes, along with the cathodic anti-corrosion layer directly on the basic material, a partial anti-corrosion system with a multilayer system made of at least one ductile metal layer and at least one hard, ceramics-containing layer. The partial anti-corrosion system may be realized according to known anti-erosion systems as configured in particular in DE 10 2004 001 392 A1 and DE 10 2007 027 335 A1, wherein the disclosure of the two cited documents is incorporated completely herein by reference.

These types of layer systems are suitable in particular for basic materials made of a titanium-based material, an iron-based material, a nickel-based material or a cobalt-based material, wherein especially the iron-based material may include steels containing chromium or iron-based superalloys and the nickel-based material may include nickel-based superalloys just as the cobalt-based material may include cobalt-based superalloys. Designated as corresponding basic materials or base alloys are the alloys whose main constituent includes the corresponding element according to which the base alloys are designated so that, in the case of an iron-based alloy, the main constituent is iron. Known basic materials can be utilized with gas turbine components, in particular components for aircraft turbines such as guide blades, rotor blades, shrouds and the like.

In the simplest case, the partial anti-corrosion system may be formed of a metal layer and a ceramic layer or ceramics-containing layer, wherein the metal layer may also be a metal alloy layer. These types of layers may then be arranged repeatedly in a layer stack. In addition, the partial anti-corrosion system may also be formed of a four-layer system, which includes a metal layer, a metal alloy layer, a metal/ceramic mixed layer and a ceramic layer. In addition, three-layer systems are also possible with, for example, a metal alloy layer, a metal/ceramic mixed layer and a ceramic layer. These layer sequences of 2, 3 or 4 layers may be provided multiple times in the partial anti-corrosion system. The individual sublayers and in this case especially the metal/ceramic mixed layer may also be configured as gradient layers, in which the composition changes in the direction of the layer thickness.

Diverse metals come into consideration for the metal layer and the metal alloy layer such as, for example, titanium, platinum, palladium, tungsten, chromium, nickel or cobalt for the metal layer, as well as metallic elements like iron, aluminum, zircon, hafnium, tantalum, magnesium, molybdenum or silicon for the metal alloy layer.

For example, the layer sequence of the partial anti-erosion system may be formed by a nickel layer, a nickel-chromium layer, a metal/ceramic layer with chromium and nitrogen, wherein chromium is present in excess, as well as a chromium-nitride layer. Alternatively, a titanium layer, a palladium layer or a platinum layer may also be provided as the first metal layer, to which a TiCrAl material or CoAlCr material is applied. Afterwards, CrAlNₗ₋ₓ or TiAlNₗ₋ₓ may be provided as the metal/ceramic mixed layer, wherein TiAlN, TiAlSiN, AlTiN or a mixture of TiN and AlN may be provided as the ceramic layer.

Furthermore, a chromium layer may be provided as the metal layer, a chromium-nickel layer may be provided as the metal alloy layer and a CrAlN layer with an excess of chromium and aluminum may be provided as the metal/ceramic mixed layer, as well as a CrAlN layer as the ceramic layer.

In the case of this type of layer sequence or even with other layer systems, diffusion barrier layers may also be provided for example in the form of a CrN layer between the cathodic anti-corrosion layer and the partial anti-corrosion system as well as within the sublayers of the partial anti-corrosion system.

Phase-stabilizing elements such as tungsten, tantalum, niobium, molybdenum, silicon, titanium, vanadium or yttrium may be provided within the individual layers, in particular the metal/ceramic layer or the metal material.

In general, the metal/ceramic mixed layer or the ceramic layer or ceramics-containing layer of the partial anti-corrosion system may be formed of oxides, nitrides, carbides or borides of the constituents of the metal layer or the metal alloy layer.

The layers of the partial anti-corrosion system may be deposited by vapor deposition, and namely in particular by physical vapor deposition (PVD).

A passive surface anti-corrosive layer, which may additionally serve as the smoothing layer, may also be formed on the partial anti-corrosion system in order to provide a clean, smooth surface of the gas turbine component.

In particular, the surface anti-corrosive layer may be formed by a sol-gel layer that is silicate-based, carbon-based, polymer-based or metal oxide-based. In general, however, passive surface anti-corrosive layers may be provided, which are applied in various ways and in the case of environmental effects protect the layer below from attack. This may be in particular layers forming or including chromium-oxide layers or aluminum-oxide layers.

By using a sol-gel layer as the surface anti-corrosive layer and/or smoothing layer, the passive surface anti-corrosive layer may be applied by painting, dip coating or the like of the liquid sol-phase and be converted to a gel layer by subsequent drying or curing under the influence of temperature.

In a similar manner, the cathodic anti-corrosion layer may be applied on the basic material as an inorganic lacquer coat by corresponding lacquering techniques such as painting, dip coating, spraying and the like. However, other application techniques of corresponding cathodic anti-corrosion layers are possible in the form of thermal spraying and vapor deposition (CVD chemical vapor deposition, PVD physical vapor deposition), etc.

In particular a cathodic anti-corrosion layer in the form of a ceramic-aluminum layer in which aluminum particles are embedded in a ceramic matrix has been proven for gas turbine components. In this case, the ceramic may include phosphates and chromates. The aluminum powder particles embedded in the ceramic may be compressed by glass bead blasting so that the A1 pigments form an Al network.

### BRIEF DESCRIPTION OF THE FIGURE

Additional advantages, characteristics and features of the present invention will be clarified in the following detailed description of an exemplary embodiment based on the enclosed drawing. The single drawing depicts a partial cross section through the surface of a gas turbine component such as, for example, a guide blade or a rotor blade having the anti-erosion coating system according to the invention.

### EXEMPLARY EMBODIMENT

The FIGURE depicts, in a partial sectional view of the surface region of a gas turbine component, such as, for example, a turbine blade or shroud, the basic material 1 of the component, on which a multilayer anti-erosion coating with the sublayers 2, 3, 4 is arranged according to the invention.

Configured directly on the basic material 1 is a cathodic anti-corrosion layer 2, which because of its lower electrochemical potential is provided as a sacrificial electrode of a forming corrosion cell. In the event of corrosive attack, for example from cracks or pores in the coating, the basic material 1 does not dissolve due to the corrosive attack, rather the cathodic anti-corrosion layer 2 dissolves first of all so that the basic material 1 is protected from the corrosive attack.

The cathodic anti-corrosion layer 2 may be formed, for example, for a basic material 1 made of a steel containing chromium by a ceramic-aluminum layer, in which aluminum particles are provided in a ceramic matrix, which have a lower electrochemical potential as compared to the steel containing chromium. Because of the aluminum that is contained, there is also an electrically conductive connection between the cathodic anti-corrosion layer 2 and the basic material 1, which is required for the formation of the local element. The cathodic anti-corrosion layer may be coordinated with the basic material and therefore have different compositions.

There is a partial anti-corrosion system on the cathodic anti-corrosion layer 2, which represents the actual anti-erosion coating and protects the basic material 1 as well as the cathodic anti-corrosion layer 2 from an erosive attack in the event of flow-mechanical stress in the gas turbine, for example an aircraft turbine.

The partial anti-corrosion system is structured of a plurality of sublayers 5, 6, 7, 8, 9. A diffusion barrier layer 5, for example in the form of a chromium-nitride layer, is provided directly in the direction of the basic material 1, i.e., on the cathodic anti-corrosion layer 2. This prevents the diffusion between the basic material 1 or cathodic anti-corrosion layer 2 and the remaining coating structure.

The partial anti-corrosion system 3 also includes a plurality of repeating layers 6, 7, 8, 9, wherein for the sake of simplicity only a single layer sequence of the multilayer system 6 to 9 is provided in the depiction of the enclosed FIGURE. However, several of these layer sequences having the sublayers 6 to 9 may be arranged on top of one another.

The multilayer system made of the sublayers 6 to 9 includes a metal layer 6, a metal alloy layer 7, a metal/ceramic layer 8 and a ceramic layer 9. The composition of the corresponding layers 6 to 9 may be coordinated with the basic material 1. Thus, for a steel containing chromium as a basic material 1, there may be a chromium layer as the metal layer 6, a chromium-nickel layer as the metal alloy layer 7, a CrAlNᵢ₋ₓ layer as the metal/ceramic layer 8 um and a CrAlN layer as the ceramic layer 9.

The metal/ceramic layer 8 may also be configured as a gradient layer, in which the proportion of the ceramic content increases in the direction of the layer thickness from the metal alloy layer 7 to the ceramic layer 9. The described exemplary embodiment for the layer composition may be selected for a basic material on a nickel-based alloy, a cobalt-based alloy, an iron-based alloy or a titanium-based alloy.

The metal layer 6 may also contain a phase-stabilizing element such as tungsten, tantalum, niobium and/or molybdenum. The metal/ceramic layer 8 or the ceramic layer 9 may also include corresponding phase-stabilizing elements such as silicon, titanium, tantalum, vanadium, molybdenum, yttrium and/or tungsten.

The diffusion barrier layer 5 made of chromium nitride may be designed to be very thin as a nanostructured monolayer.

Additional diffusion barrier layers (not shown) may be provided between the individual sublayers 6 to 9 of the multilayer system 3.

To conclude the anti-erosion coating system, a passive surface anti-corrosive layer 4 may be provided on the surface.

The passive surface anti-corrosive layer 4 may also cause a smoothing of the surface and is therefore designated as a smoothing layer. In the exemplary embodiment presented above, the smoothing layer or surface anti-corrosive layer 4 may be configured as a sol-gel layer that is silicate-based, carbon-based, polymer-based or metal oxide-based. The passive surface anti-corrosive layer 4 may already prevent the formation of a corrosion cell with the involvement of the basic material 1 so that to begin with, in a first step, the dissolution of the cathodic anti-corrosion layer 2 as the sacrificial anode is also prevented.

The passive surface anti-corrosive layer may be applied by a sol-gel method, wherein the liquid sol is applied on the multilayer system 3 by painting, spraying or brushing and then dried and cured by a heat treatment.

In same manner, the cathodic anti-corrosion layer 2 in the form of an inorganic lacquer system can be applied by lacquering techniques such as painting, spraying, dip coating and the like, wherein likewise a subsequent heat treatment at temperatures around 550° C. may be performed in order to consolidate the aluminum particles.

The partial anti-corrosion system 3 may be deposited by physical vapor deposition (PVD).

Although the present invention has been described in detail on the basis of the exemplary embodiments, it is self-evident for a person skilled in the art that the invention is not restricted to these exemplary embodiments, but that in fact modifications or changes within the scope of protection, which is defined by the enclosed claims, are possible. In particular, individual features of those presented may be omitted or different combinations of the described features may be carried out. In particular, the present invention includes all combinations of all features presented.

1.-16. (canceled)

17. A gas turbine component, comprising:
a basic material;
an anti-corrosion layer disposed on a surface of the basic material, wherein the anti-corrosion layer has a lower electrochemical potential than the basic material and wherein the anti-corrosion layer provides cathodic corrosion protection; and
a partial anti-erosion coating system disposed on the anti-corrosion layer, wherein the partial anti-erosion coating system comprises a multi-layer system including a ductile metal layer and a hard, ceramics-containing layer.

18. The gas turbine component according to claim 17, wherein the basic material is a steel containing Cr, a nickel-based superalloy, an iron-based superalloy, titanium-based alloy or a cobalt-based superalloy.

19. The gas turbine component according to claim 17, wherein the ductile metal layer is a metal layer and/or a metal alloy layer and wherein the hard, ceramics-containing layer is a metal/ceramic mixed layer and/or a ceramic layer.

20. The gas turbine component according to claim 19, wherein the metal layer includes titanium, platinum, palladium, tungsten, chromium, nickel or cobalt and/or the metal alloy layer includes at least one component which is selected from the group including titanium, platinum, palladium, tungsten, chromium, nickel, cobalt, iron, aluminum, zircon, hafnium, tantalum, magnesium, molybdenum and silicon.

21. The gas turbine component according to claim 20, wherein the metal/ceramic mixed layer and/or the ceramic layer includes at least one oxide, nitride, carbide and/or boride of the metal layer and/or of the metal alloy layer.

22. The gas turbine component according to claim 17, wherein the partial anti-erosion system includes a diffusion barrier layer disposed on the anti-corrosion layer.

23. The gas turbine component according to claim 22, wherein the diffusion barrier layer includes CrN.

24. The gas turbine component according to claim 17, further comprising a passive surface anti-corrosion layer and/or a smoothing layer disposed on the partial anti-erosion system.

25. The gas turbine component according to claim 24, wherein the passive surface anti-corrosion layer and/or the smoothing layer is a chromium-oxide layer or an aluminum-oxide layer and/or a sol-gel layer that is silicate-based, carbon-based, polymer-based or metal oxide-based.

26. The gas turbine component according to claim 17, wherein the anti-corrosion layer is an inorganic lacquer coat.

27. The gas turbine component according to claim 17, wherein the anti-corrosion layer is a ceramic-aluminum layer.

28. The gas turbine component according to claim 24, wherein an electrochemical potential of the anti-corrosion layer is less than an electrochemical potential of the basic material, wherein an electrochemical potential of the partial anti-erosion system is greater than the electrochemical potential of the basic material, and wherein an electrochemical potential of the passive surface anti-corrosion layer is very much greater than the electrochemical potential of the basic material.

29. The gas turbine component according to claim 17, wherein the gas turbine component is a rotor blade, a guide blade or a shroud.

30. A method for producing an anti-erosion coating system, comprising the steps of:
a) applying a cathodic anti-corrosion layer on a surface of a gas turbine component; and
b) applying a multi-layer partial anti-erosion system using physical vapor deposition on the cathodic anti-corrosion layer.

31. The method according to claim 30, further comprising the step of applying a diffusion barrier layer between the cathodic anti-corrosion layer and the multi-layer partial anti-erosion system.

32. The method according to claim 30, further comprising the step of applying a passive surface anti-corrosive layer on the multi-layer partial anti-erosion system.

33. The method according to claim 30, wherein the cathodic anti-corrosion layer is applied by painting, spraying, dip coating, thermal spraying, chemical vapor deposition or physical vapor deposition.

34. The method according to claim 32, wherein the passive surface anti-corrosive layer is applied by painting, spraying, dip coating, thermal spraying, chemical vapor deposition or physical vapor deposition.
